(19) United States
(12) Patent Application Publication
(10) Pub. No.: US 2016/0351648 A1
(43) Pub. Date: Dec. 1, 2016

(54) DUAL DISPLAY TECHNOLOGIES DISPLAY

(71) Applicant: Sony Mobile Communications Inc., Tokyo (JP)

(72) Inventors: Martin Ek, Lund (SE); Martin Grip, Hollviken (SE); Alexander Hunt, Tygelsjo (SE)

(21) Appl. No.: 14/722,528

(22) Filed: May 27, 2015

(51) Int. Cl. H01L 27/32; H01L 51/52

(52) U.S. Cl. CPC H01L 27/3267; H01L 27/3232; H01L 51/5237; H01L 27/323; H01L 27/3276; H01L 2251/308

(57) ABSTRACT

A display device comprising an organic light emitting diode (OLED) display; and an electrophoretic display (EPD). The OLED display and the EPD share a common backplane, the common backplane comprising thin-film transistors (TFTs) of the OLED display and TFTs of the EPD thereon.

### BACKGROUND

A device, such as a mobile device or a wearable device, offers various services to its user. One problem confronted by designers and manufacturers is to provide a display that has superior image quality and is able to sustain an “always on” state due to low power consumption.

### SUMMARY

According to one aspect, a display device may comprise an organic light emitting diode (OLED) display; and an electrophoretic display (EPD), wherein the OLED display and the EPD share a common substrate. The common substrate may comprise thin-film transistors (TFTs) of the OLED display and TFTs of the EPD thereon.

According to another aspect, a user device may comprise a housing, wherein the housing supports a display, and wherein the display may comprise an OLED display; and an EPD. The OLED display and the EPD may share a common backplane. The common backplane may comprise TFTs of the OLED display and TFTs of the EPD.

According to yet another aspect, a display device may comprise an OLED display; and an EPD. The OLED display and the EPD may share a common substrate. The common substrate may comprise TFTs of the OLED display and TFTs of the EPD. Also, the OLED display may comprise an on-cell sensor layer.

### DESCRIPTION OF THE DRAWINGS

FIG. 1A illustrates a cross-sectional, schematic view of an exemplary embodiment of a display comprising an organic light emitting diode (OLED) display and an electrophoretic display (EPD);

FIG. 1B illustrates a cross-sectional, schematic view of another exemplary embodiment of a display comprising an OLED display and an EPD;

FIG. 1C illustrates a cross-sectional, schematic view of yet another exemplary embodiment of a display comprising an OLED display and an EPD;

FIG. 2A illustrates an exemplary OLED pixel circuit;

FIG. 2B illustrates an exemplary EPD pixel circuit;

FIG. 3A illustrates a top view of an exemplary embodiment of a dual display technologies display and a dual driver system;

FIG. 3B illustrates a top view of another exemplary embodiment of a dual display technologies display and a dual driver system;

FIG. 4A illustrates a top view of an exemplary embodiment of a dual display technologies display including OLED wiring;

FIG. 4B illustrates a top view of the another exemplary embodiment of a dual display technologies display including OLED wiring;

FIGS. 5A-5C illustrate top views of exemplary embodiments of arrangements of a dual display technologies display;

FIG. 6 illustrates an exemplary user device in which an embodiment of a dual display technologies display may be implemented;

FIG. 7 illustrates another exemplary user device in which an embodiment of a dual display technologies display may be implemented; and

FIG. 8 illustrates exemplary components of the user devices depicted in FIGS. 6 and 7.

### DETAILED DESCRIPTION OF PREFERRED EMBODIMENTS

The following detailed description refers to the accompanying drawings. The same reference numbers in different drawings may identify the same or similar elements.

Differences between display technologies may include power consumption characteristics and quality of image, as well as structural differences, such as whether a backlight system is needed, etc. Given that different display technologies may offer different advantages, designers and manufacturers may wish to integrate two different display technologies into a single display. However, the selection of which display technologies to integrate and how to integrate them can present various structural and operational issues.

Typically, an OLED display unit comprises a power supply, an anode, a cathode, an emissive layer, and a conductive layer. The OLED panel is supported by a substrate. Additionally, typically, an EPD unit comprises a power supply and an EPD foil sandwiched between two electrodes.

According to an exemplary embodiment, a display includes a common backplane (e.g., substrate) for two different thin-film transistor (TFT) layout structures. According to an exemplary embodiment, the two different TFT structures comprise an organic light emitting diode (OLED) TFT and an electrophoretic display (EPD) TFT. According to an exemplary implementation, in order to deposit the two different TFT structures on the common backplane, masks may be used during a photolithography process to enable the two different pixel structures to be deposited on the same backplane (e.g., substrate, a TFT substrate).

According to an exemplary embodiment, the display, which comprises the OLED display and the EPD, comprises a common top layer. According to an exemplary embodiment of the EPD, a stackup of the EPD comprises a reference layer. The reference layer comprises an indium tin oxide (ITO) layer. For example, the ITO layer serves as a ground or a reference layer. Additionally, according to an exemplary embodiment of the OLED display, a stackup of the OLED display comprises an on-cell sensor layer. The on-cell sensor layer also comprises the ITO layer. The ITO layer comprises a touch sensor pattern that provides touch functionality (e.g., touch and/or touchless functionality).

According to other embodiments, with reference to the dual display technologies display, the EPD comprises the ITO layer as the reference layer, and the OLED display does not comprise the ITO layer (e.g., with no touch functionality). According to still other embodiments, the EPD comprises the ITO layer as the reference layer, and the OLED comprises some other conventional or separate touch layer.

According to an exemplary embodiment, the dual display technologies display comprises a dual driver system that supports the two different display technologies. According to an exemplary implementation, the dual driver system comprises a driver for the EPD and a driver for the OLED display. According to an exemplary implementation, the dual driver system comprises two separate driver integrated circuits (ICs), in which each driver supports one of the display technologies. According to another exemplary implementation, the dual driver system comprises a single driver IC that supports both display technologies.

According to an exemplary embodiment, an EPD passive border provides an area to route wiring from the OLED TFT to the dual driver system. According to another exemplary embodiment, the EPD TFT area includes space to route wiring from the OLED TFT to the dual driver system.

According to an exemplary embodiment, the arrangement of the two display technologies is based on an image arrangement to be presented via the display. According to an exemplary embodiment, the EPD passive border matches a color of a background of the EPD. For example, the EPD passive border can be set to any color the rest of the EPD can present. The EPD passive border may be seen or considered as one large pixel. The EPD passive border may change color like any other pixel. According to such an embodiment, the dual display technologies display may appear borderless to a user.

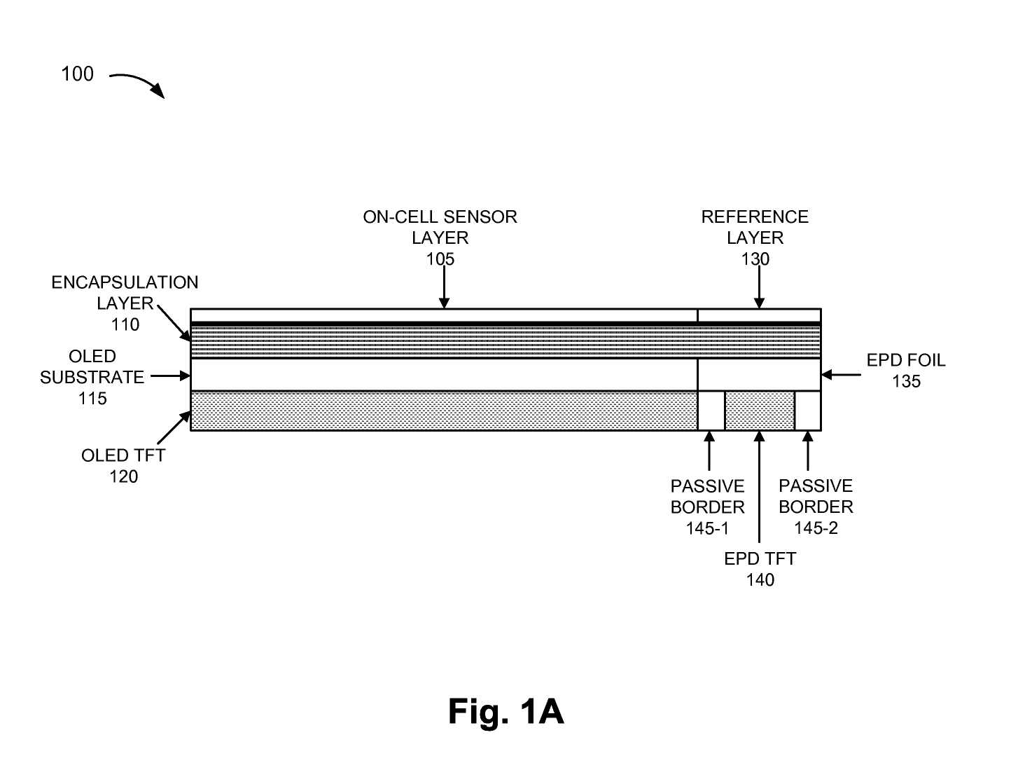

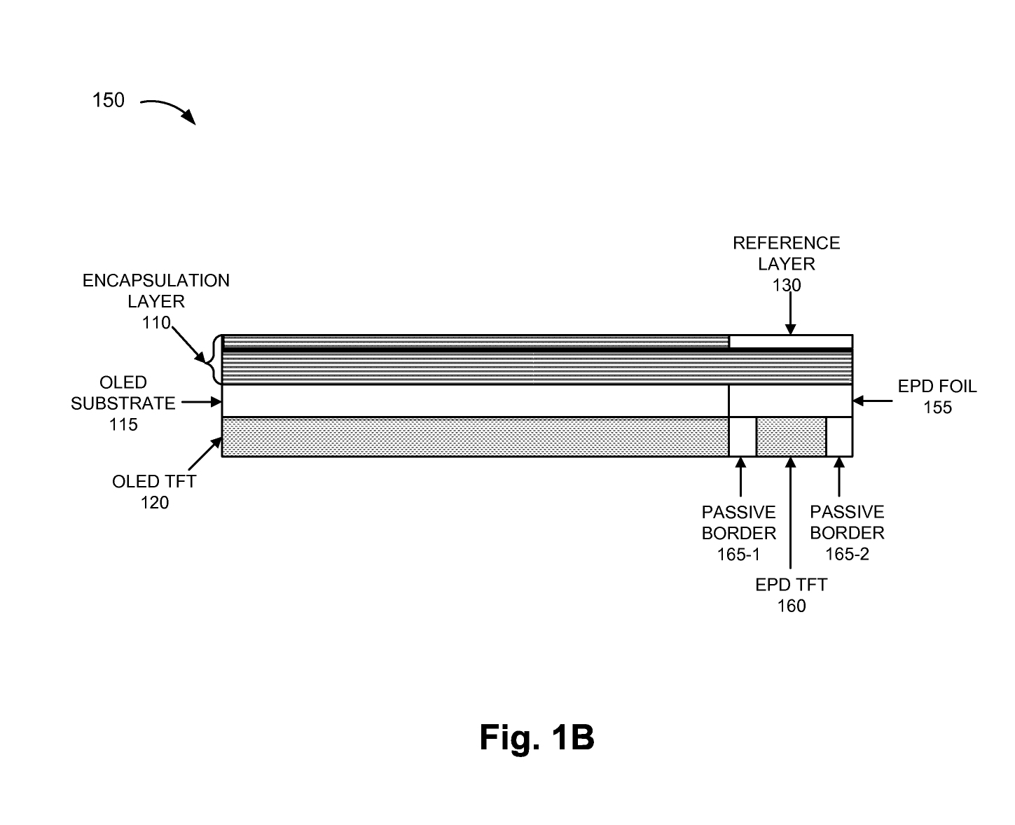

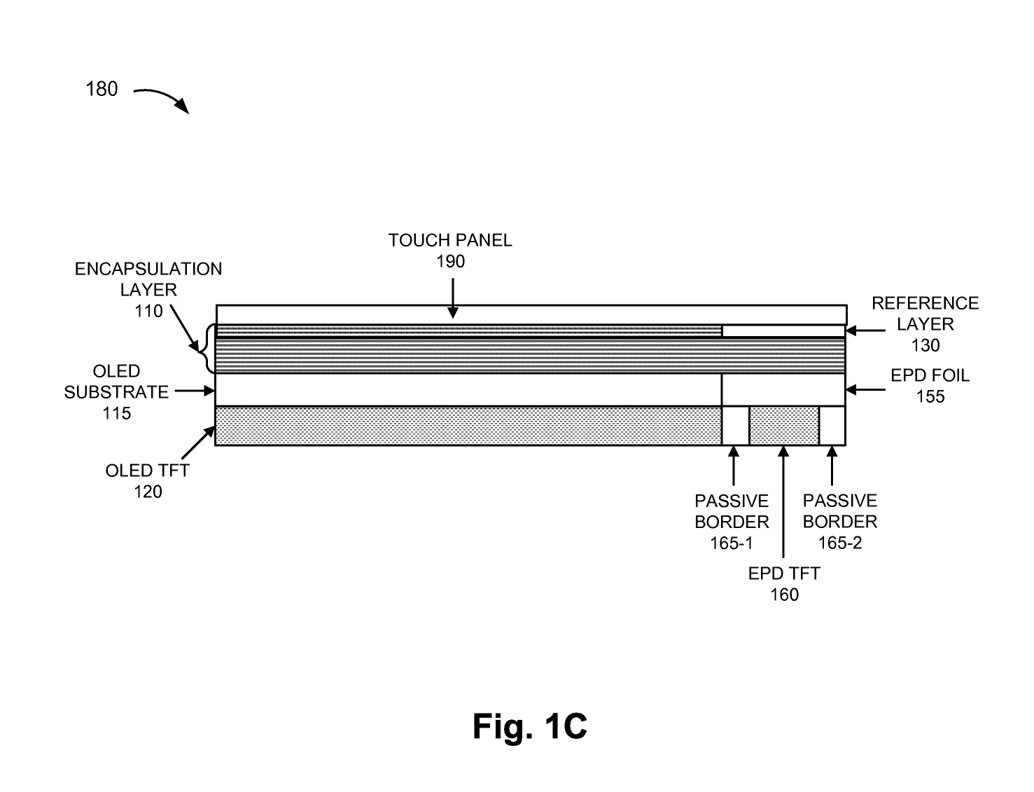

FIG. 1A illustrates a cross-sectional, schematic view of an exemplary embodiment of a dual display technologies display 100 comprising an OLED display and an EPD. As illustrated, a dual display technologies display 100 comprising an on-cell sensor layer 105, an encapsulation layer 110, an OLED substrate 115, and an OLED TFT 120. Additionally, dual display technologies display 100 comprises a reference layer 130, an EPD foil 135, an EPD TFT 140, and passive borders 145-1 and 145-2 (also referred to as passive borders 145 or generally as passive border 145). According to an exemplary embodiment, as illustrated, the dual display technologies (i.e., OLED and EPD) have a side-by-side arrangement.

On-cell sensor layer 105 comprises a layer that provides touch functionality. According to an exemplary embodiment, on-cell sensor layer 105 and reference layer 130 comprise the same material. For example, on-cell sensor layer 105 and reference layer 130 comprise indium tin oxide (ITO). On-cell sensor layer 105 comprises a printed touch panel sensor (e.g., a touch screen panel (TSP) ITO pattern). Reference layer 130 is described further below. As illustrated, on-cell sensor layer 105 and reference layer 130 are co-planar.

Encapsulation layer 110 comprises a layer that encapsulates both OLED substrate 115 and EPD foil 135. Encapsulation layer 110 may comprise glass or other suitable material (e.g., an oxide layer, a polymer layer, etc.). Encapsulation layer 110 may serve as a protective layer (e.g., to prevent dust, oxygen, and moisture damage). As illustrated, encapsulation layer 110, which is usually formed in the OLED stackup, extends over EPD foil 135. As illustrated, encapsulation layer 110 is below on-cell sensor layer 105 and reference layer 130. Encapsulation layer 110 may be formed on an electrode of OLED substrate 115.

OLED substrate 115 comprises an organic stack and conducting layers (e.g., electrodes). For example, the organic material may comprise a fluorescent material, a phosphorescent material, or other type of organic molecules or polymers (e.g., an electroluminescent conductive polymer, etc.). The conducting layers may serve as the anode and the cathode. OLED substrate 115 may comprise any conventional OLED stack or stacks comprising organic materials and conducting layers.

OLED TFT 120 and EPD TFT 140 comprise a common substrate on which both OLED TFTs and EPD TFTs are formed. For example, a TFT arrangement for OLED and EPD may be formed on a common backplane. The substrate may comprise silicon or other suitable material (e.g., low temperature polysilicon (LTPS), indium gallium zinc oxide (IGZO), etc.). As previously described, masks may be used, for example, during a photolithography process to make the two different pixel structures associated with OLED and EPD on the same substrate. For example, a first array of OLED pixels and a second array of EPD pixels may be formed.

Reference layer 130 comprises a layer that serves as a common electrode (e.g., a transparent electrode layer, a counter electrode layer, etc.). According to an exemplary embodiment, reference layer 130 comprises a same material as on-cell sensor layer 105. For example, reference layer 130 comprises indium tin oxide (ITO).

EPD foil 135 comprises a foil layer. For example, EPD foil 135 may comprise a metal material (e.g., aluminum, etc.) or some other suitable electrophoretic imaging layer (e.g., an electronic ink film).

Passive border 145 comprises an electrophoretic display material. Passive border 145 may have a color that is substantially the same as the background of the EPD. For example, passive border 145 is switchable between colors that are available in the EPD. The number of colors and type of colors may vary depending on the implementation. For example, passive border 145 may be switchable of up to four different colors. Passive border 145 may also be switchable to a color other than white and black. In this way, a viewer of the dual display technologies display may have the impression that a displayed image extends towards the edge (e.g., borderless) of the display module. Passive border 145 may be used to conceal electrical connections for both the EPD portion and the OLED portion of the dual display technologies display.

FIG. 1B illustrates a cross-sectional, schematic view of another exemplary embodiment of a dual display technologies display 150 comprising an OLED display and an EPD. In contrast to dual display technologies display 100, dual display technologies display 150 does not comprise on-cell sensor layer 105. Rather, encapsulation layer 110 is built up to a level substantially planar to or planar to reference layer 130 (e.g., co-planar). According to such an embodiment, the dual display technologies display will not comprise touch functionality with respect to the OLED portion nor the EPD portion of dual display technologies display 150.

FIG. 1C illustrates a cross-sectional, schematic view of yet another exemplary embodiment of a dual display technologies display 180 comprising an OLED display and an EPD. According to such an exemplary embodiment, in contrast to dual display technologies display 150, a touch panel 190 may be formed on top of encapsulation layer 110 and reference layer 130. In this embodiment, the dual display technologies display comprises touch functionality with respect to the OLED portion and the EPD portion of the dual display technologies display.

With respect to each of FIGS. 1A, 1B, and 1C, the proportion of the OLED display relative to the EPD of the dual display technologies display is exemplary. Additionally, the size of an element or a layer in FIGS. 1A-1C is exemplary and illustrated for the convenience of explanation. Accordingly, the size of a layer or an element, as depicted, should not unduly limit the embodiments of the dual display technologies display, as described herein. Additionally, when a layer or an element is referred to as being “formed on” another layer or another element, the phrase “formed on” may be directly or indirectly formed. Thus, according some embodiments, an intervening layer or an intervening element may also be present. Additionally, the term “layer” is not intended to limit the configuration of the various elements used to construct the dual display technologies display (e.g., by implying a planar construction or boundaries which are coextensive with the adjacent layers.)

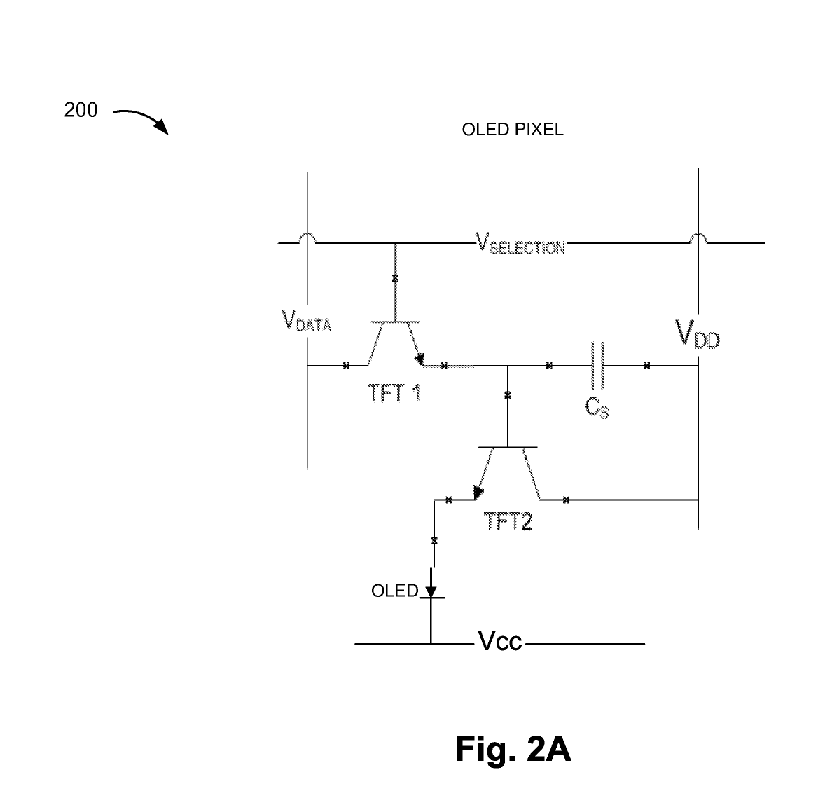

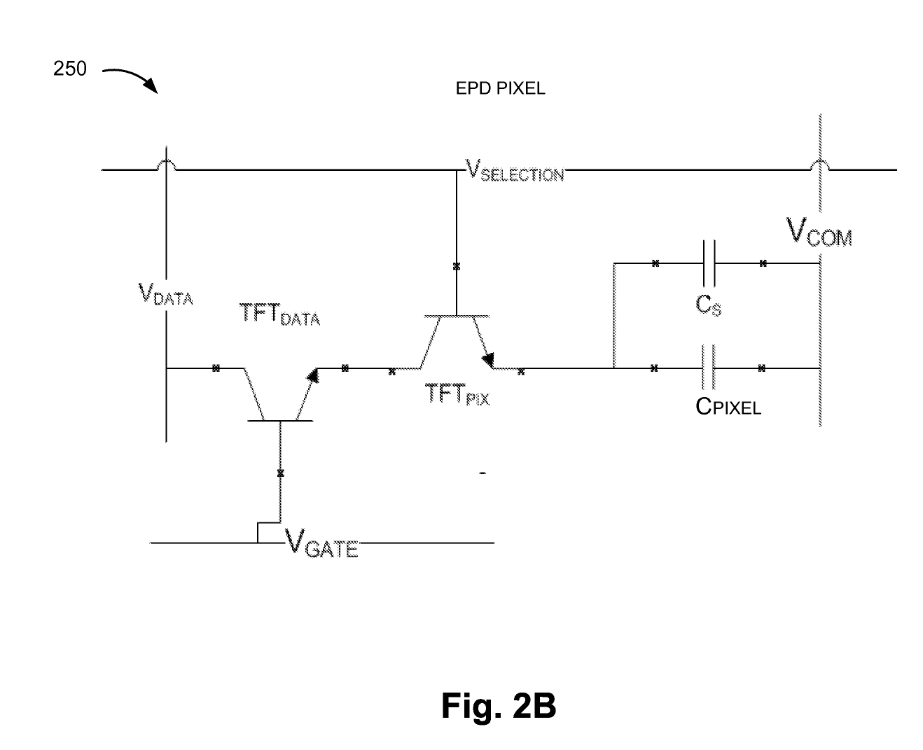

FIG. 2A illustrates an exemplary OLED pixel circuit. As illustrated, the OLED pixel circuit comprises two TFTs, such as an address TFT and a driver TFT. Additionally, the OLED pixel circuit comprises a storage capacitor. The OLED pixel circuit (e.g., 2TIC) may be implemented for an active-matrix (AM) OLED display. FIG. 2B illustrates an exemplary EPD pixel circuit. As illustrated, the EPD pixel circuit comprises two TFTs and a storage capacitor and a pixel capacitor. For example, the pixel capacitor may be used to reduce the effect of the parasitic overlap capacitance. While the OLED pixel circuit and the EPD pixel circuit are exemplary, as illustrated and described, these circuits are similar. As such, according to an exemplary embodiment, a dual display technologies display comprising an OLED TFT and an EPD TFT may be deposited on a same substrate gloss. According to an exemplary implementation, in order to deposit the two different TFT structures, masks may be used during a photolithography process to enable the two different pixel structures to be deposited on the same substrate.

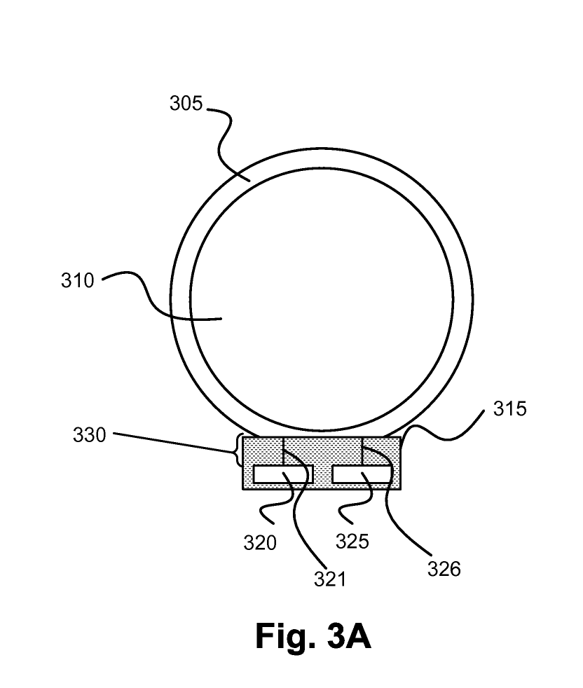

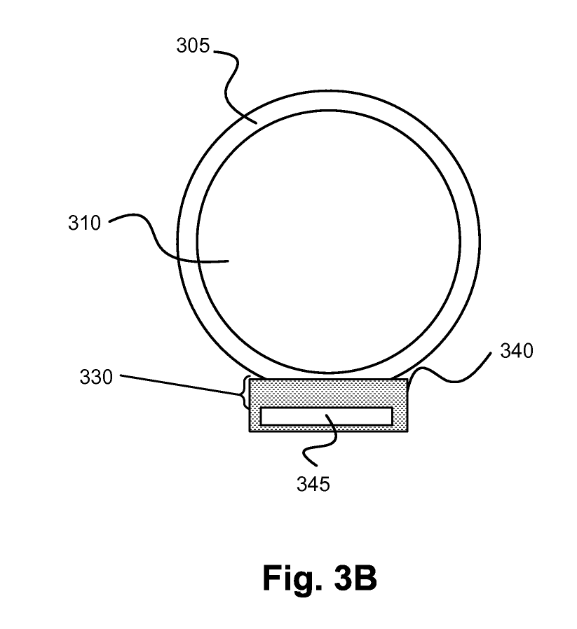

FIG. 3A illustrates a top view of an exemplary embodiment of a dual display technologies display and a dual driver system. As illustrated, the display configuration is substantially rounded and comprises an EPD portion 305 and an OLED portion 310. A dual driver system 315 provides a dual driver system for EPD portion 305 and OLED portion 310. According to an exemplary embodiment, dual driver system 315 comprises an EPD driver 320 and an OLED driver 325. According to another exemplary embodiment, as illustrated in FIG. 3B, dual driver system 340 comprises an integrated driver 345, which supports both EPD portion 305 of the display and OLED portion 310 of the display. However, using separate drivers, as illustrated in FIG. 3A, may be easier and cheaper to implement since existing drivers may be used.

Dual driver system 315 comprising EPD driver 320 and OLED driver 325, or dual driver system 340 comprising integrated driver 345 may be implemented as a chip-on-glass (COG), a chip-on-foil, a chip-on-flex, a flexible printed circuit (FPC), etc. However, a chip-on-foil implementation may minimize the size of the border to a greater degree than a chip-on-glass.

Referring to both FIGS. 3A and 3B, a space 330, which is sufficient in dimension, is needed to be able to route driver signals, via wiring, from dual driver system 315 or dual driver system 340 to the respective OLED TFTs and the EPD TFTs. According to an exemplary implementation, the driver signals for the OLED TFTs may be routed, via OLED wiring 326, counterclockwise, and the driver signals for the EPD TFTs may be routed, via EPD wiring 321, clockwise. According to such an implementation, wire crossings may be avoided between the OLED wirings and the EPD wirings supporting each display technology. According to another exemplary implementation, the driver signals for the OLED TFTs may be routed, via OLED wiring, clockwise, and the driver signals for the EPD TFTs may be routed, via EPD wiring, counterclockwise. In a similar fashion, according to this alternative implementation, wire crossings may be avoided.

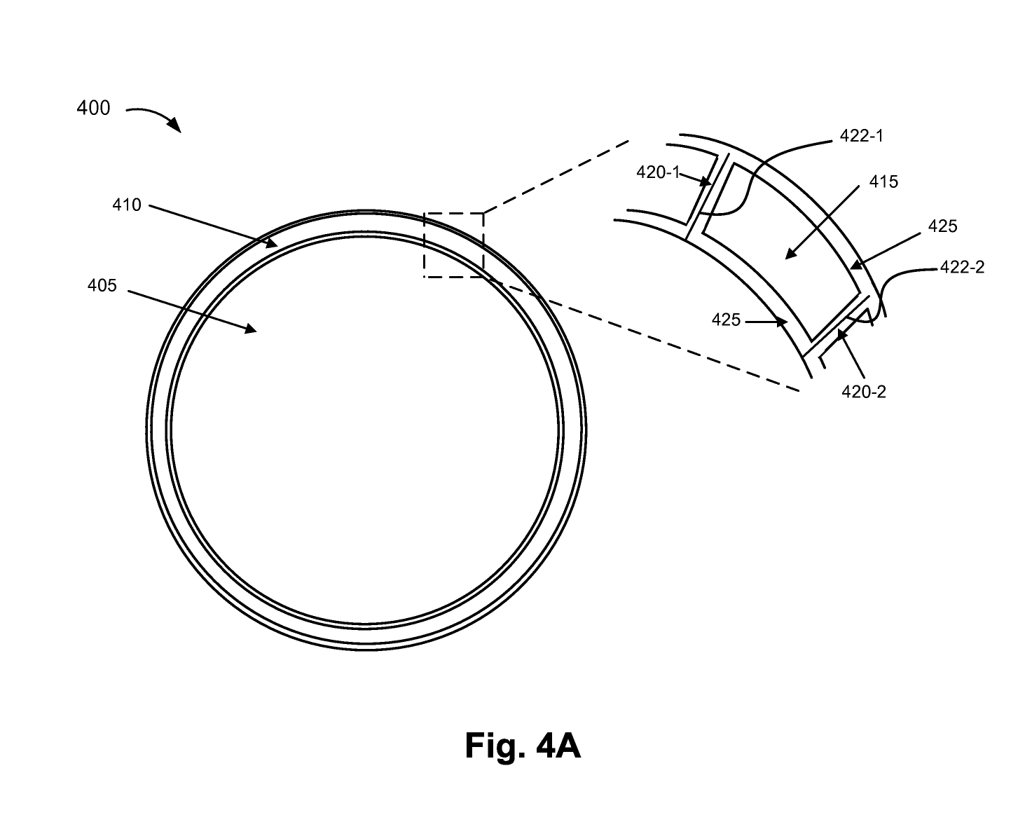

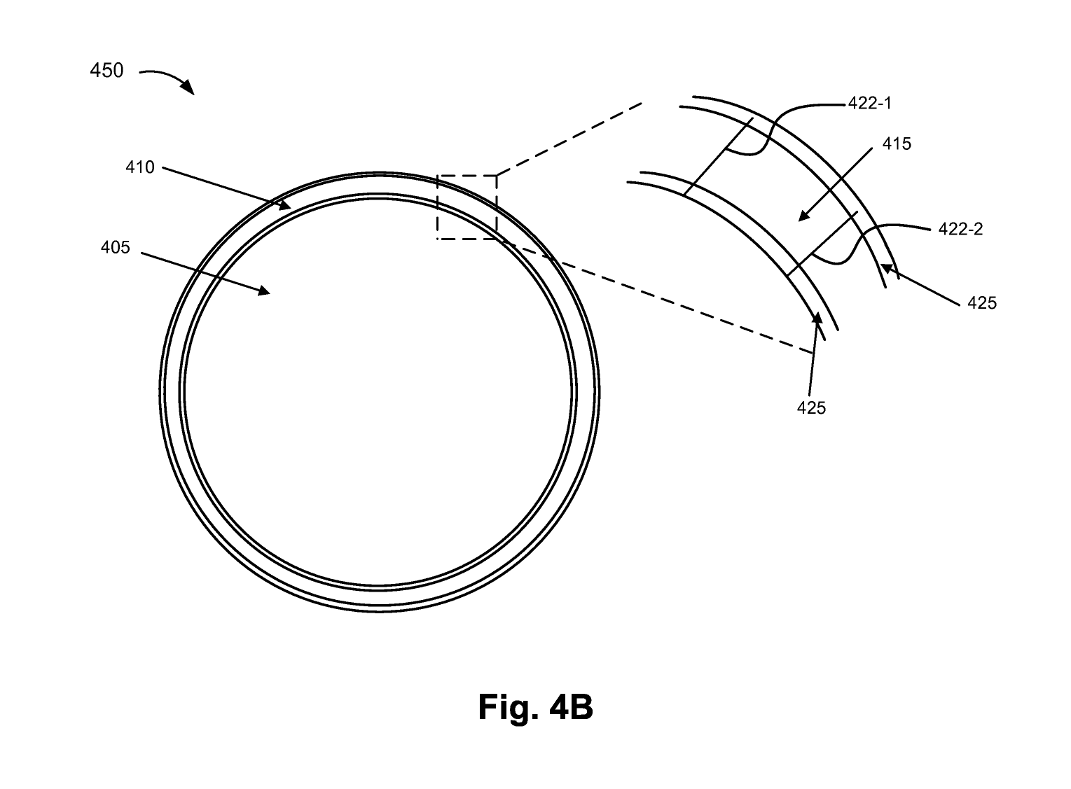

FIG. 4A illustrates a top view of an exemplary embodiment of a dual display technologies display including OLED wires. As illustrated, a dual display technologies display 400 comprises an OLED portion 405 and an EPD portion 410. As indicated by the dotted-lined box, a close-up view of EPD portion 410 is illustrated. As illustrated in the close-up view, an EPD TFT portion 415 is provided, which is surrounded by a passive border 425. Slits 420-1 and 420-2 (also referred to as slits 420 or generally as slit 420) each provides a passageway for OLED wires 422-1 and 422-2 (also referred to as OLED wires 422 or generally as OLED wire 422) to be routed from OLED portion 405 (e.g., an OLED TFT) to the border. This configuration is similar to that previously illustrated in, for example, FIG. 1A.

FIG. 4B illustrates a top view of another exemplary embodiment of a dual display technologies display including OLED wires. In contrast to FIG. 4A, this arrangement does not comprise slits 420 that provide a passageway for OLED wires 422. Rather, OLED wires 422 are routed through available space of the EPD TFT portion 415. For example, OLED wires 422 may be provided on the substrate level. By way of further example, since EPD is a reflective display technology, space under EPD foil 135 (e.g., EPD TFT 140 of the common substrate/backplane) may be used for OLED wiring. OLED wires 422 may comprise a V_selection line and a V_data line (e.g., V_{CC} and V_{DD}), which are common for all pixels. Further to this point, as an example and with reference to EPD TFT 140, less than a 0.2 μm pitch line/space can be achieved on LTPS.

According to an exemplary embodiment, passive border 425 does not show any graphical content but has the same color as EPD TFT portion 415. In this way, dual display technologies displays 400 and 450 may appear to be borderless. For example, passive border 425 may change color from white to black, as a whole. According to other examples, passive border 425 may change between colors different from black and/or white.

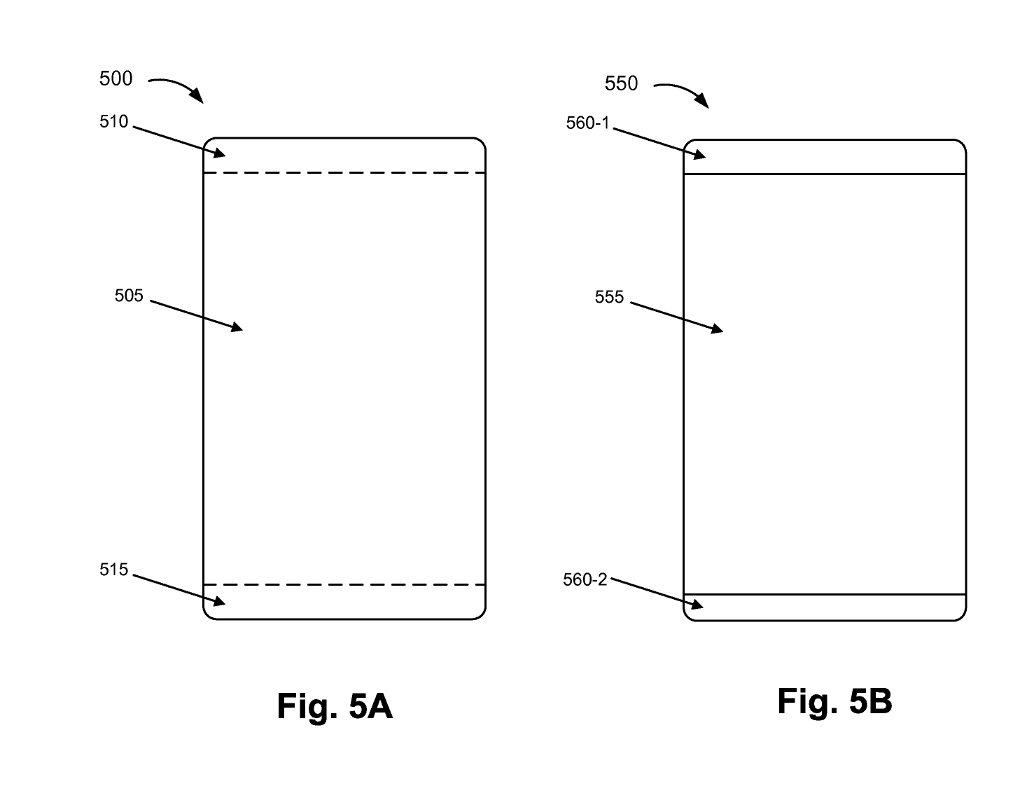

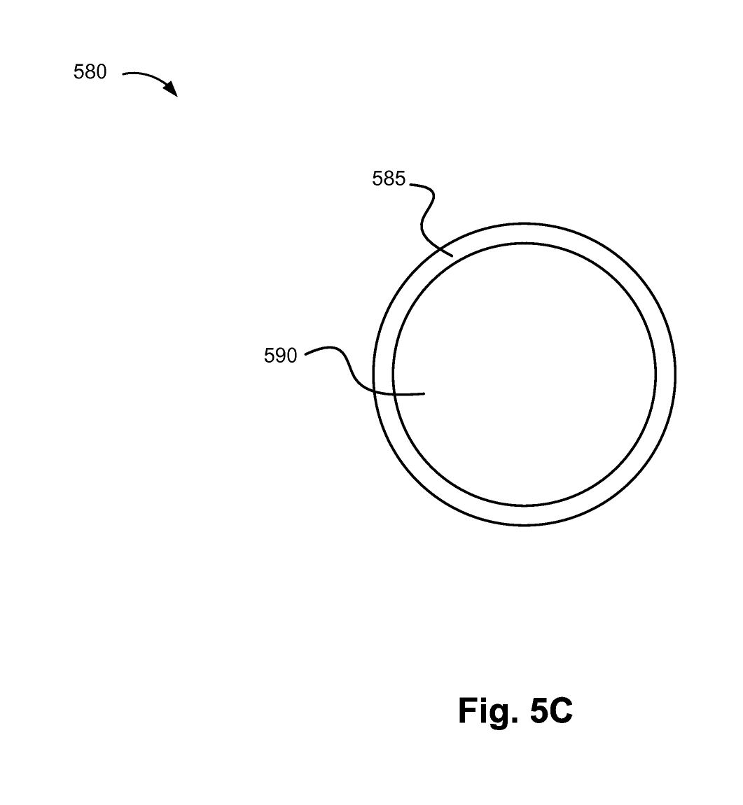

As previously described, the arrangement of the two display technologies may be based on an image arrangement to be presented via the dual display technologies display. For example, an “always on” image may be displayed via the EPD of the dual display technologies display since the EPD offers minimal power consumption. Additionally, for example, the OLED display of the dual display technologies display may be used for displaying high quality images on an as-needed basis. FIG. 5A illustrates a top view of an exemplary embodiment of an arrangement for a dual display technologies display. As illustrated, a dual display technologies display 500 includes an OLED display 505 and, an EPD 510 or an EPD 515. OLED display 505 may be used to display a main portion of a desktop or a home screen, such as application icons, etc. According to this example, the EPD 510 or 515 may be located at the top of the display (e.g., EPD 510) or at the bottom of the display (e.g., EPD 515). EPD 510 or EPD 515 may be used to display other types of information, such as various icons pertaining to battery life, connection state, mode of user device, type of network to which the user device is connected, current time (e.g., hour, minutes, seconds), day (e.g., Monday, Tuesday, etc.), a prompt to unlock the user device, a message, etc. Additionally, EPD 510 or EPD 515 may be used to display a notification bar. The notification bar may indicate incoming messages, updates, other forms of user notifications, etc.

FIG. 5B illustrates a top view of an exemplary embodiment of another arrangement for a dual display technologies display. According to this example, a dual display technologies display 550 comprise an OLED display 555, and EPDs 560-1 and 560-2, which are located at a top and a bottom of the dual display technologies display.

FIG. 5C illustrates a top view of an exemplary embodiment of yet another arrangement for a dual display technologies display. According to this example, a dual display technologies display 580 comprises an EPD 585 and an OLED display 590. According to this arrangement, EPD 585 may, for example, display numbers and the ends of clock hands within EPD 585, and OLED display 590 may display the remaining portion of the clock hands, or any other graphical user interface (e.g., a home screen, an unlock screen, etc.). For example, while the ends of clock hands and the numbers of the clock are displayed within EPD 585, OLED display 590 may or may not display the remaining portion of the clock (e.g., the remaining portion of the clock hands or any other time-based information (e.g., date (e.g., month, day, year, etc.)).

The arrangements illustrated in FIGS. 5A-5C are exemplary. Accordingly, variations of the exemplary arrangements are possible and the description is not intended to be restrictive, nor is it intended to provide an exhaustive treatment pertaining to every possible arrangement that may be configured. Additionally, the size and/or shape of the EPD and the size and/or shape of the OLED display are exemplary and not intended to be restrictive, nor is the description, as set forth herein, intended to provide an exhaustive treatment pertaining to every possible size and/or shape that may be configured.

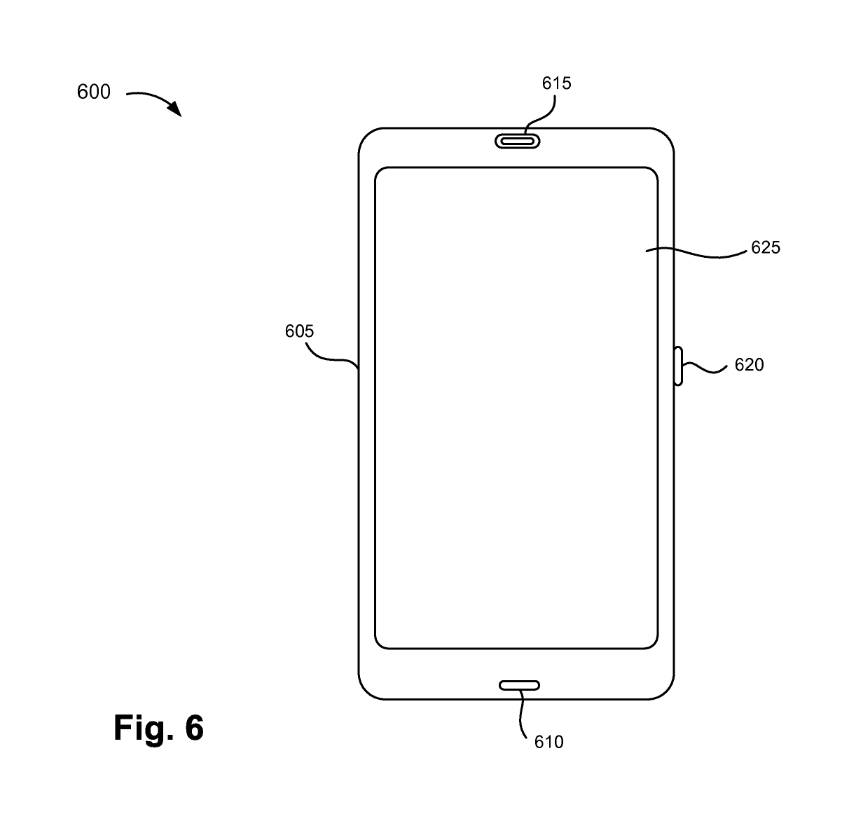

Embodiments of a display comprising dual display technologies, as described herein, may be implemented within various types of user devices. FIG. 6 illustrates an exemplary user device 600 in which an embodiment of a display comprising dual display technologies may be implemented. While illustratively speaking based on FIG. 6, user device 600 may be representative of, for example, a smartphone, a cellphone, or a personal digital assistant (PDA), user device 600 may be implemented as various other types of user devices. For example, user device 600 may take the form of a tablet device, a data organizer, a picture capturing device, a video capturing device, a Web-access device, a computer, a palmtop device, a netbook, a gaming device, a location-aware device, a music playing device, a television, or some other type of consumer device that comprises a display. Alternatively, user device 600 may be implemented as a non-consumer device, a non-mobile device, or any other form of an electronic device. As illustrated in FIG. 6, user device 600 comprises a housing 605, a microphone 610, a speaker 615, a button 620, and a display 625. Display 625 comprises a dual display technologies display according to an exemplary embodiment, as described herein. According to other embodiments, user device 600 may comprise fewer components, additional components, different components, and/or a different arrangement of components than those illustrated in FIG. 6 and described herein.

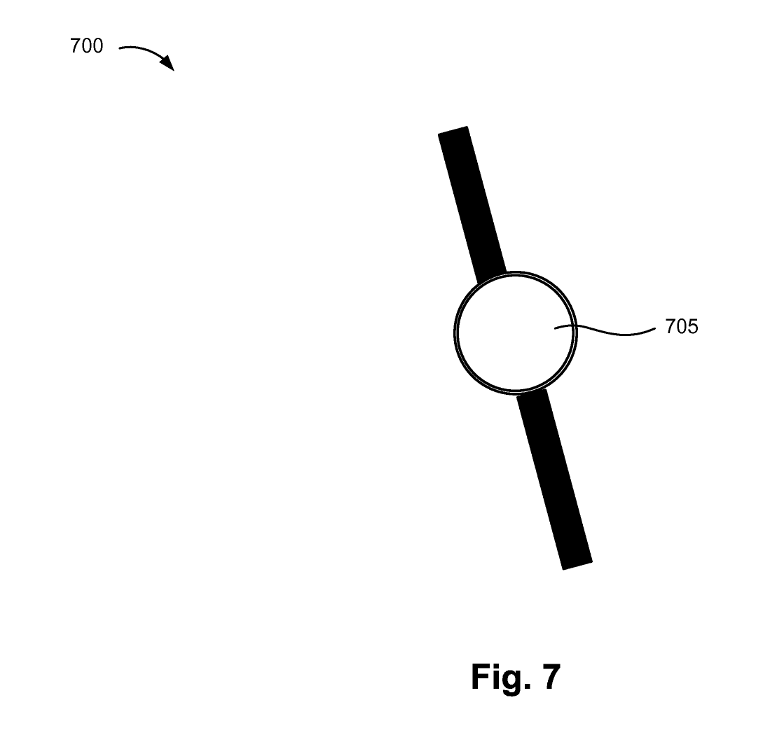

FIG. 7 illustrates another example of a user device 700 in which an embodiment of a dual display technologies display may be implemented. In this example, user device 700 is representative of a wearable device (e.g., a watch-type user device) that comprises a circular display 705. Circular display 705 comprises a dual display technologies display according to an exemplary embodiment, as described herein.

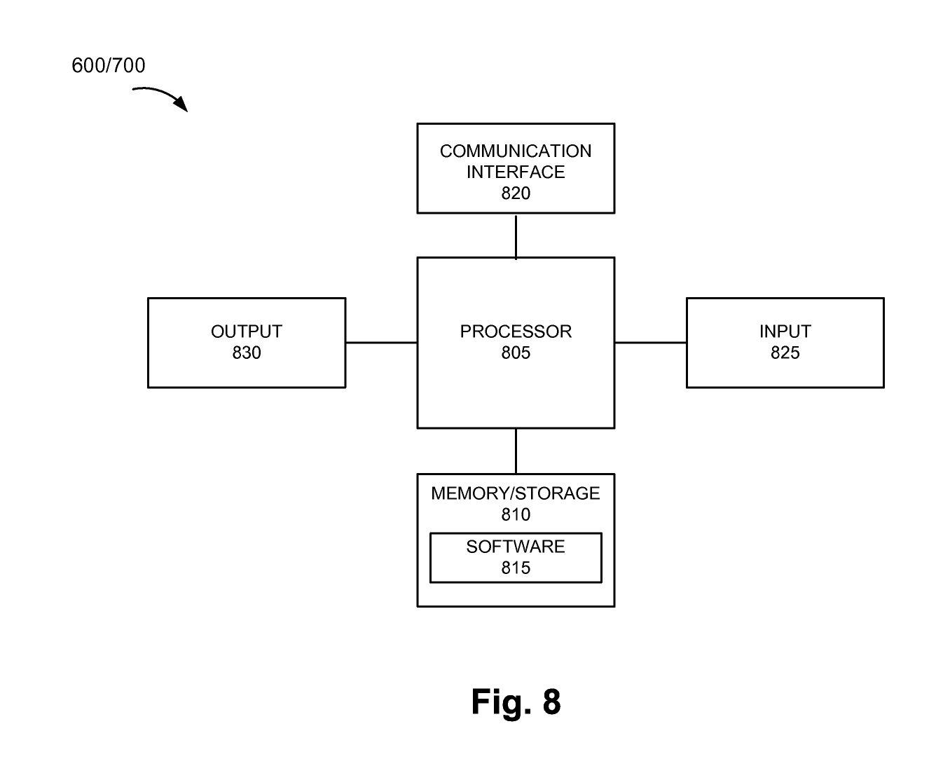

FIG. 8 illustrates exemplary components of user devices 600 and 700 (simply referred to as user device 600). As illustrated, according to an exemplary embodiment, user device 600 comprises a processor 805, memory/storage 810, software 815, a communication interface 820, an input 825, and an output 830. According to other embodiments, user device 600 may comprise fewer components, additional components, different components, and/or a different arrangement of components than those illustrated in FIG. 8 and described herein. For example, user device 600 may comprise a power source (e.g., a battery).

Processor 805 comprises one or multiple processors, microprocessors, data processors, co-processors, and/or some other type of component that interprets and/or executes instructions and/or data. Processor 805 may be implemented as hardware (e.g., a microprocessor, etc.) or a combination of hardware and software (e.g., a system-on-chip (SoC), an application-specific integrated circuit (ASIC), etc.). Processor 805 performs one or multiple operations based on an operating system and/or various applications or programs (e.g., software 815).

Memory/storage 810 comprises one or multiple memories and/or one or multiple other types of storage mediums. For example, memory/storage 810 may include a random access memory (RAM), a dynamic random access memory (DRAM), a cache, a read only memory (ROM), a programmable read only memory (PROM), and/or some other type of memory. Memory/storage 810 may include a hard disk (e.g., a magnetic disk, an optical disk, a magneto-optic disk, a solid state disk, etc.).

Software 815 comprises an application or a program that provides a function and/or a process. Software 815 may include firmware. By way of example, software 815 may comprise a telephone application, a multi-media application, an e-mail application, a contacts application, a calendar application, an instant messaging application, a web browsing application, a location-based application (e.g., a Global Positioning System (GPS)-based application, etc.), a camera application, etc. Software 815 comprises an operating system (OS). For example, depending on the implementation of user device 600, the operating system may correspond to iOS, Android, Windows Phone, Symbian, or another type of operating system (e.g., proprietary, BlackBerry OS, Windows, Linux, etc.).

Communication interface 820 permits user device 600 to communicate with other devices, networks, systems, etc. Communication interface 820 may include one or multiple wireless interfaces and/or wired interfaces. Communication interface 820 may include one or multiple transmitters, receivers, and/or transceivers. Communication interface 820 operates according to one or multiple protocols, a communication standard, and/or the like.

Input 825 permits an input into user device 600. For example, input 825 may include a button, a switch, a touch pad, an input port, speech recognition logic, and/or a display (e.g., a touch display, a touchless display). Output 830 permits an output from user device 600. For example, output 830 may include a speaker, a display, a light, an output port, and/or some other type of output component.

User device 600 may perform a process and/or a function in response to processor 805 executing software 815 stored by memory/storage 810. By way of example, instructions may be read into memory/storage 810 from another memory/storage 810 or read into memory/storage 810 from another device via communication interface 820. The instructions stored by memory/storage 810 causes processor 805 to perform the process or the function. Alternatively, user device 600 may perform a process or a function based on the operation of hardware (processor 805, etc.).

The foregoing description of embodiments provides illustration, but is not intended to be exhaustive or to limit the embodiments to the precise form disclosed. Accordingly, modifications to the embodiments described herein may be possible.

The terms “a,” “an,” and “the” are intended to be interpreted to include one or more items. Further, the phrase “based on” is intended to be interpreted as “based, at least in part, on,” unless explicitly stated otherwise. The term “and/or” is intended to be interpreted to include any and all combinations of one or more of the associated items.

The terms “comprise,” “comprises” or “comprising,” as well as synonyms thereof (e.g., include, etc.), when used in the specification is meant to specify the presence of stated features, integers, steps, or components but does not preclude the presence or addition of one or more other features, integers, steps, components, or groups thereof. In other words, these terms are to be interpreted as inclusion without limitation.

The word “exemplary” is used herein to mean “serving as an example.” Any embodiment or implementation described as “exemplary” is not necessarily to be construed as preferred or advantageous over other embodiments or implementations.

Spatially relative terms, such as “beneath,” “below,” “lower,” “above,” “upper,” and the like, may be used herein for ease of description to describe one element's or feature's relationship to another element or feature as illustrated in the figures. For example, if the element in the figure is turned over, an element described as “below” or “beneath” another element or another feature would then be oriented “above” the other element or the other feature. Thus, for example, the exemplary terms “below” or “beneath” may encompass both an orientation of above and below depending on the orientation of a display device or a user device. In the instance that the display device may be oriented in a different manner (e.g., rotated at 90 degrees or at some other orientation), the spatially relative terms used herein should be interpreted accordingly.

In the preceding specification, various embodiments have been described with reference to the accompanying drawings. However, various modifications and changes may be made thereto, and additional embodiments may be implemented, without departing from the broader scope of the invention as set forth in the claims that follow. The specification and drawings are accordingly to be regarded as illustrative rather than restrictive.

In the specification and illustrated by the drawings, reference is made to “an exemplary embodiment,” “an embodiment,” “embodiments,” etc., which may include a particular feature, structure or characteristic in connection with an embodiment(s). However, the use of the phrase or term “an embodiment,” “embodiments,” etc., in various places in the specification does not necessarily refer to all embodiments described, nor does it necessarily refer to the same embodiment, nor are separate or alternative embodiments necessarily mutually exclusive of other embodiment(s). The same applies to the term “implementation,” “implementations,” etc.

No element, act, or instruction described in the present application should be construed as critical or essential to the embodiments described herein unless explicitly described as such.

Use of ordinal terms such as “first,” “second,” “third,” etc., in the claims to modify a claim element does not by itself connote any priority, precedence, or order of one claim element over another, but are used merely as labels to distinguish one claim element having a certain name from another element having a same name (but for use of the ordinal term) to distinguish the claim elements.

1. A display device comprising:
an organic light emitting diode (OLED) display;
an electrophoretic display (EPD), wherein the OLED display and the EPD share a common substrate, the common substrate comprising:
thin-film transistors (TFTs) of the OLED display and TFTs of the EPD thereon; and
a driver system that drives the OLED display and the EPD;
wherein the OLED display is adjacent the EPD, and the EPD is interposed between the OLED display and the EPD;
wherein OLED wires connecting the driver system and the OLED display pass through an area of the substrate dedicated to the EPD;
wherein the area of the substrate dedicated to the EPD comprises the TFTs of the EPD and a passive border having a first portion extending along a length of an edge of the EPD adjacent the OLED display, the first portion of the passive border interposed between the TFTs of the EPD and the TFTs of the OLED display; and
wherein the passive border switchable as a whole between colors available in the EPD and the passive border not showing graphical content.

2. The display device of claim 1, wherein an encapsulation layer of the OLED display is formed on both an electrode layer of the OLED display and an electrophoretic imaging layer of the EPD.

3. The display device of claim 2, wherein the encapsulation layer is between a reference layer of the EPD and the electrophoretic imaging layer of the EPD.

4. The display device of claim 3, wherein the OLED display comprises an on-cell sensor layer.

5. The display device of claim 4, wherein the on-cell sensor layer and the reference layer comprise indium tin oxide (ITO), and are co-planar.

6. The display device of claim 1, comprising:
a touch panel, wherein the touch panel extends over the EPD and the OLED display.

7. (canceled)

8. A user device comprising:
the display device of claim 1; and
a housing, wherein the housing supports the display.

9-11. (canceled)

12. The user device of claim 8, comprising:
a touch panel, wherein the touch panel extends over the EPD and the OLED display; and
one of a chip-on-glass, a chip-on-foil, a chip-on-flex, or a flexible printed circuit, wherein the chip-on-glass, the chip-on-foil, the chip-on-flex, or the flexible printed circuit comprises the driver system of the display, and wherein EPD wiring from the driver system to the TFTs of the EPD and the OLED wiring from the driver system to the TFTs of the OLED display do not comprise a wiring crossing.

13-14. (canceled)

15. The user device of claim 8, wherein the user device is a wearable device or a mobile device, and the user device further comprising:
a power source;
a communication interface;
a memory, wherein the memory stores instructions; and
a processor, wherein the processor is configured to execute the instructions.

16-19. (canceled)

20. The display device of claim 1, wherein a color of the passive border matches a background of the EPD.

21. The display device of claim 1, wherein the passive border has a second portion extending along a length of an edge of the EPD opposite the OLED display.

22. The display device of claim 21, wherein the passive border has a third portion between the first and second portions and separating areas of the TFTs of the EPD.

23. The display device of claim 22, wherein the wires connecting the driver system and the OLED display traverse slits in the third portion of the passive border.

24. The display device of claim 1, wherein the wires connecting the driver system and the OLED display traverse areas of the TFTs of the EPD.

25. The display device of claim 24, wherein the wires connecting the driver system and the OLED display traverse areas of the TFTs of the EPD in a space between an EPD foil and the TFTs of the EPD, the EPD foil overlies the TFTs of the EPD and the passive border.

26. The display device of claim 1, wherein the lack of graphical content shown on the passive border and the passive border switchable as a whole causing the display device to appear borderless.
